(19) United States
(12) Patent Application Publication
(10) Pub. No.: US 2009/0035454 A1
(43) Pub. Date: Feb. 5, 2009

(54) Assembly of Encapsulated Electronic Components to a Printed Circuit Board

(75) Inventor: Joseph C. Fjelstad, Maple Valley, WA (US)

Correspondence Address: The TPL Group, 20400 Stevens Creek Blvd., Fifth Floor, Cupertino, CA, 95014, US

(73) Assignee: Occam Portfolio LLC, Cupertino, CA (US)

(21) Appl. No.: 12/182,043

(22) Filed: Jul. 29, 2008

Related U.S. Application Data
(63) Continuation-in-part of application No. 12/119,287, filed on May 12, 2008.
Application No. 12/119,287 is a continuation-in-part of application No. 12/163,870, filed on Jun. 27, 2008.
Application No. 12/163,870 is a continuation-in-part of application No. PCT/US08/65131, filed on May 29, 2008.
Application No. PCT/US08/65131 is a continuation-in-part of application No. 12/170,426, filed on Jul. 9, 2008.
(60) Provisional application No. 60/962,626, filed on Jul. 31, 2007.
(60) Provisional application No. 60/963,822, filed on Aug. 6, 2007.
(60) Provisional application No. 60/966,643, filed on Aug. 28, 2007.
(60) Provisional application No. 61/038,564, filed on Mar. 21, 2008.
(60) Provisional application No. 61/039,059, filed on Mar. 24, 2008.
(60) Provisional application No. 61/075,238, filed on Jun. 24, 2008.

(51) Int. Cl. B05D 5/00; H05K 7/00

(52) U.S. Cl. 427/96.2; 427/58; 361/760

(57) ABSTRACT

Electrical components 402, 504, 506 are placed on a carrier 508. Then the components are encapsulated in an electrically insulating material 404. The carrier 508 is removed and the leads 414 of the encapsulated components are registered to intermediate connectors 412 in a central bonding, or joining, material 406 and to respective leads 410 of a printed circuit board 408. The components, central bonding material, and printed circuit board are then joined and interconnected.

### CROSS-REFERENCE TO RELATED APPLICATIONS

This application claims the benefit of U.S. Provisional Application No. 60/962,626, filed on Jul. 31, 2007, hereby incorporated by reference in its entirety; U.S. Provisional Application No. 60/963,822, filed on Aug. 6, 2007, hereby incorporated by reference in its entirety; U.S. Provisional Application No. 60/966,643, filed on Aug. 28, 2007, hereby incorporated by reference in its entirety; U.S. Provisional Application No. 61/038,564, filed on Mar. 21, 2008, hereby incorporated by reference in its entirety; U.S. Provisional Application No. 61/039,059 filed on Mar. 24, 2008, hereby incorporated by reference in its entirety; and U.S. Provisional Application No. 61/075,238 filed on Jun. 24, 2008, hereby incorporated by reference in its entirety.

This application is a continuation-in-part application of pending U.S. patent application Ser. No. 12/119,287, ELECTRONIC ASSEMBLIES WITHOUT SOLDER AND METHODS FOR THEIR MANUFACTURE; U.S. patent application Ser. No. 12/163,870, ELECTRONIC ASSEMBLIES WITHOUT SOLDER AND METHODS FOR THEIR MANUFACTURE; PCT Patent Application No. PCT/US2008/065131, ELECTRONIC ASSEMBLIES WITHOUT SOLDER AND METHODS FOR THEIR MANUFACTURE; and U.S. patent application Ser. No. 12/170,426, ELECTRONIC ASSEMBLIES WITHOUT SOLDER AND METHODS FOR THEIR MANUFACTURE, hereby incorporated by reference in their entirety.

### COPYRIGHT NOTICE AND PERMISSION

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The present invention relates generally to the field of electronic assembly and more specifically, but not exclusively, to the manufacture and assembly of encapsulated electronic components to a printed circuit board by means of an adhesive layer having embedded intermediate conductors.

### BACKGROUND OF THE INVENTION

Historically, most electronic products have been assembled using a solder material and a soldering process. This has always had disadvantages, and a number of new trends are revealing or exacerbating other disadvantages.

One set of disadvantages relates to solder materials themselves. Since the earliest days of the electronics industry tin/lead type solders (e.g., Sn63/Pb37) have been widely used. Unfortunately, both tin and especially lead have serious chemical disadvantages. For these two metals, mining the ores, refining it, working with the refined metals during manufacturing, being exposed to the substances in manufactured products, and disposing of the products at the ends of their life cycles are all potentially damaging to human health and to the environment.

Recently human health and environmental concerns about tin/lead type solders have resulted in the Directive on the Restriction of the Use of Certain Hazardous Substances in Electrical and Electronic Equipment (commonly referred to as the Restriction of Hazardous Substances Directive or RoHS) in the European Union. This directive restricts the use of six hazardous materials, including lead, in the manufacture of various types of electronic and electrical equipment. This directive is also closely linked with the Waste Electrical and Electronic Equipment Directive (WEEE) 2002/96/EC, which sets collection, recycling, and recovery targets for electrical goods. Together these directives are part of a growing world-wide legislative initiative to solve the problem of electronic device waste.

To some extent the electronics industry has always been searching for a practical substitute for tin/lead type solders, and legislative initiatives like those just noted are now motivating a number of changes. Today a common substitute for tin/lead type solders are SAC type solder varieties, which are alloys containing tin (Sn), silver (Ag), and copper (Cu). But this is merely a compromise. Mining, refining, working during manufacturing, exposure from manufactured products, and disposal are still all issues for tin, silver, and copper. It therefore suffices here to say that the undue use of some materials, like solder, is generally undesirable in electronic assemblies. Another set of disadvantages in the solder-based assembly of electronic products is the heat-based processes that are inherently required. The use of heat on and around many electronic components has always been undesirable. As a general principle, the heating of electronic components increases their failure rate and beyond a certain point outright damages such components. Tin/lead solders melt at relatively low temperatures, and their use has generally been tolerable for many components. This is not as frequently the same for SAC type solders, however, which melt at much higher temperatures. When SAC type solders are used, the likelihood of component damage is much higher, resulting in assemblies that fail during post-manufacturing testing as well as in-the-field failures. Additionally, generating and managing the heat during manufacturing have energy, safety, and financial costs. In addition, the undue use of lead-based manufacturing processes, like soldering, is also generally undesirable in electronic assemblies.

Increasingly yet another set of disadvantages in the solder-based assembly of electronic products is related to the “adding” of materials. When a material, like solder, is added between two components to hold them together, the additional material inherently has to occupy some space. The use of liquid-state materials, like solder in its liquid stage, in manufacturing often requires additional space around leads, terminals, and pads because both product and process designs need to account for the ability of liquid to flow easily and thus to potentially short to other leads, terminals, pads, etc. Liquid surface tension effects are also usually a major consideration in such designs, as liquid solders have high surface tensions. These all thus are factors as designers increasingly strive to miniaturize electronic assemblies. So the undue use of additional material, including solder, in manufactured assemblies and manufacturing processes is generally undesirable.

FIG. 1 (prior art) is a side cross-section view of a conventional solder-based assembly 100 including a printed circuit board (PCB 102) and a component package 104. The package 104 includes an electrical component 106 having gull wing terminals or leads 108 (one lead 108 shown). A solder joint 110 connects the lead 108 to a terminal pad 112 on the PCB 102. Elsewhere on the PCB 102 insulating material 114 prevents material from the solder joint 110 flowing to where it can short to other solder joints, leads, or terminal pads. In the particular example shown, the PCB 102 is a multi-layer type where a conductor filled through hole 116 connects the terminal pad 112 to one or more conductive traces 118.

This prior art approach has a number of disadvantages. It uses solder, which may contain undesirable materials (e.g., lead) and which requires lead-based manufacturing processes (i.e., soldering). As implied above, solder from the solder joint 110 can flow, thus motivating the use of the insulating material 114 and various additional design concerns to avoid having the solder joint 110 short to other solder joints, leads, or terminal pads. This also complicates both the external structure of PCB 102, as well as the internal structure of the PCB 102. Furthermore, since the solder at the solder joint 100 inherently occupies some space, its presence increases the height of the overall assembly 100.

FIG. 2 (prior art) is a side cross-section view of another conventional solder-based assembly 200, including a printed circuit board (PCB 202) and a different component package 204. The package 204 here includes an electrical component 206, leads 208 (one lead 208 shown), a supports 210, and an insulating base 212. The PCB 202 here includes a terminal pad 214, an insulating material 216, and a through hole 218 connecting the terminal pad 214 to one or more conductive traces 220.

Here a ball solder 222 connects the lead 208 to the terminal pad 214. But in most respects, particularly including the disadvantages already discussed for the assembly 100, the assembly 200 is largely the same.

FIG. 3 (prior art) is a side cross-section view of a solderless assembly connection apparatus 300 in accord with U.S. Pat. No. 5,959,840 (Collins, Avery, Suy, and Tichane). See also U.S. Pat. Nos. 5,504,988, 5,615,086, and 5,881,453. This configuration includes a printed circuit board (PCB 302), a component package 304, and a chuck 306. The package 304 has gull wing terminals or leads 308. Because of the gull wing leads' 308 natural spring, the package 304 snaps into the chuck 306. The chuck 306 is registered with the PCB 302. Pressure applied to chuck 306 brings the gull wing leads 308 into electrical contact with respective leads 310 on PCB 302.

An optional elastic Z axis connector 312 may be located between the gull wing leads 308 and leads 310 the PCB 302. The purpose of the connector 312 is to cushion the connection and to help form a hermetic seal for cavity 314. Another option is to introduce a heat conductive gas or fluid into the cavity 314 to aid in heat dissipation generated by package 304.

The shortcomings of apparatus 300 include that its primary use is limited to gull wing lead electrical components. There is also the prospect of damage to the package 304 and leads 308, 310 from the pressure applied to chuck 306. Additional hardware is needed to attach the chuck to the PCB 302; and coolant introduced into cavity 314 is an additional complexity.

### BRIEF SUMMARY OF THE INVENTION

Accordingly, it is an object of the present invention to provide improved assemblies of electronic components and methods for their manufacture.

It is a further object of the present invention to provide a solderless connection apparatus joining electrical components and printed circuit boards, so that numerous electronic components may be electrically interconnected to the printed circuit board.

The electrical circuit apparatus includes an electrical component encapsulated in electrical insulating material in which leads of the electrical component are exposed.

A method of forming the apparatus includes placing the components on a carrier, encapsulating the components in an electrically insulating material, and removing the carrier.

The electrical circuit apparatus may further include an electrical component encapsulated in electrical insulating material so that leads of the electrical component connect with intermediate connectors within a joining material, and so that the intermediate connectors connect with leads on a printed circuit board.

A method of connecting electrical components to a printed circuit board includes placing the components on a carrier, encapsulating the components in an electrically insulating material, removing the carrier, registering component leads with respective printed circuit board leads, placing an electrically conductive joining material with intermediate conductors between encapsulated components and the printed circuit board, and joining the encapsulated components, the joining material, and the printed circuit board so that the component leads are in electrical communication with respective printed circuit board leads by way of the intermediate conductors. The electrically conductive joining material may be surrounded by an adhesive joining material to provide additional support.

These and other objects and advantages of the present invention will become clear to those skilled in the art in view of the description of the best presently known mode of carrying out the invention and the industrial applicability of the preferred embodiment as described herein and as illustrated in the figures of the drawings.

### BRIEF DESCRIPTION OF THE SEVERAL VIEWS OF THE DRAWING(S)

The purposes and advantages of the present invention will be apparent from the following detailed description in conjunction with the appended figures of drawings in which:

FIG. 1 (prior art) is a side cross-section view of a conventional solder-based circuit assembly including a printed circuit board (PCB) and a component package.

FIG. 2 (prior art) is a side cross-section view of another conventional solder-based circuit assembly including a PCB and a different component package.

FIG. 3 (prior art) is a side cross-section view of a solderless circuit assembly apparatus.

FIG. 4 is a partial side cross-section view of a circuit assembly made in accordance with the present invention.

FIG. 5 is a step in the making of the circuit assembly (shown in cross-section view) in which components are mounted on a carrier.

FIG. 6 is a step in the making of the circuit assembly (shown in cross-section view) in which components are encapsulated in electrically insulating material.

FIG. 7 is a step in the making of the circuit assembly (shown in cross-section view) in which the carrier is removed from encapsulated components.

FIG. 8 is an exploded view of the circuit assembly (shown in cross-section) showing a step in which a joining material is placed between the encapsulated components (without the carrier) and a PCB.

FIG. 9 is a side cross-section view of a completed circuit assembly.

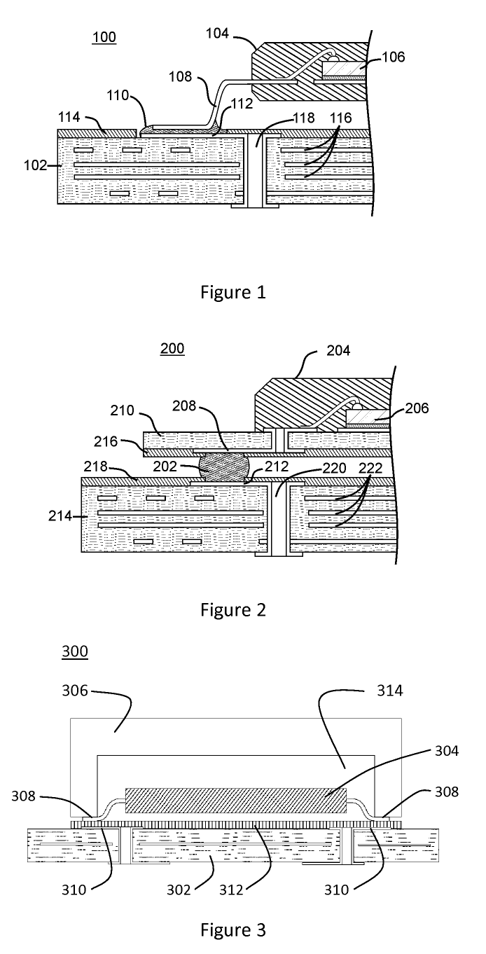

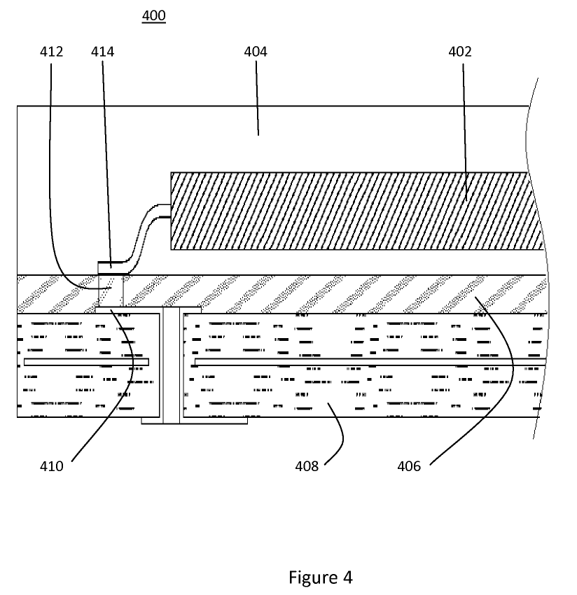

In the various figures of the drawings, like references are used to denote like or similar elements or steps.

### DETAILED DESCRIPTION OF THE INVENTION

Circuit assembly 400, FIG. 4, is a partial view of a completed assembly made in accordance with the present invention. Electrical component 402, including gull wing lead 414, is encapsulated with electrically insulating material 404. Optionally, electrically insulating material 404 is made of heat conducting material. The gull wing lead 414 is shown for illustrative purposes; it will be apparent to one skilled in the art that electrical components including, but not limited to, area array IC packages (e.g. pin or post grid array (PGA), land grid array (LGA) and the like), quad flat pack (OFP), quad flat non leaded (QFN), discrete, and digital or analog components may be substituted. The components are preferably pretested and burned in prior to assembly to assure their proper operation and viability.

The subassembly of component 402 and material 404 rest on joining material 406 so that lead 414 is in electrical contact with intermediate connector 412, which may be a conductive adhesive, conductive powder or other suitable material. Joining material 406, in turn, is disposed on PCB 408 with connecter 412 registered to PCB lead 410 so that connector 412 is in electrical contact with lead 410. The effect of the assembly 400 is that component 402, through lead 414, connector 412, and lead 410, is in proper position and in electrical connection with PCB 408.

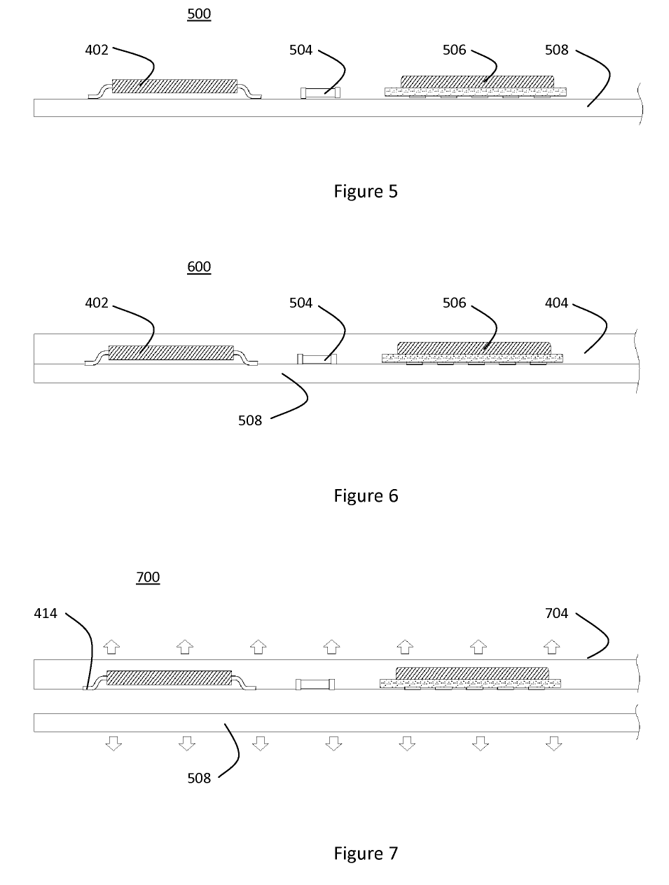

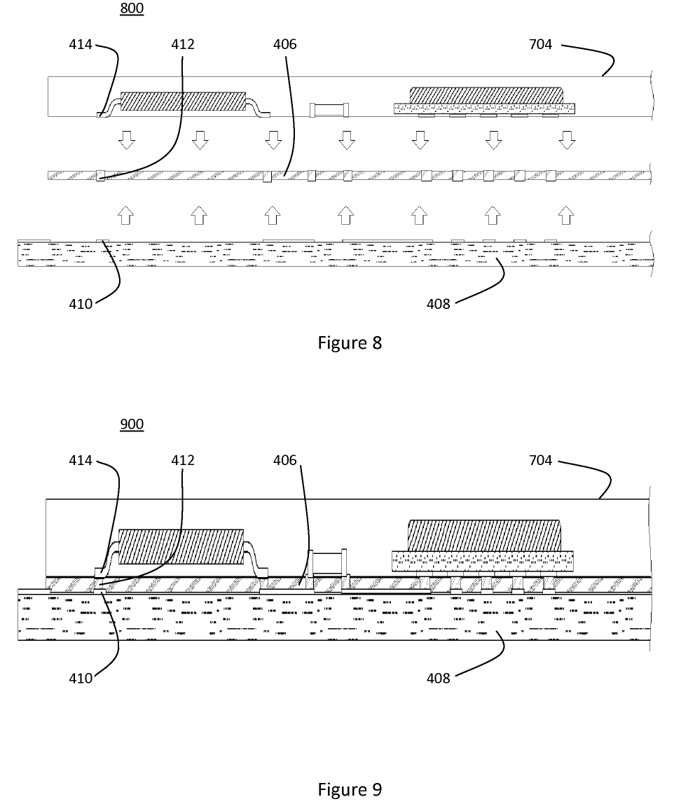

Step 500, FIG. 5, shows a step in the creation of assembly 400. Components, such as gull wing 402, discrete 504, and LGA 506 components, are placed on temporary carrier 508, components 402, 504, and 506 may be adhered and secured by adhesive. A next step 600 includes encapsulating components 402, 504, and 506, while connected to carrier 508, with electrically insulating material 404.

In step 700, FIG. 7, the carrier 508 is removed and discarded (or reused) and subassembly 704 is released for further assembly. At this point, leads (and terminations) such as lead 414 are exposed and an optional testing step may be employed to verify function of the components. Step 800 shows the positioning of subassembly 704 in regard to joining material 406, which in turn, is positioned with PCB 408. Leads and terminations, such as lead 414, are registered in respect to intermediate connector 412 which in turn is registered to PCB lead 410. Joining material 406 may be screen printed, stenciled, ink jetted or otherwise disposed on either PCB 408, subassembly 704, or both surfaces.

Completed circuit assembly 900, FIG. 9, shows the connection of subassembly 704, joining material 406, and PCB 408. Adhesive may be used to adhere the connective joints. Lead 414, intermediate connector 412, and lead 410 are in proper position and in electrical connection.

While various embodiments have been described above, it should be understood that they have been presented by way of example only, and that the breadth and scope of the invention should not be limited by any of the above described exemplary embodiments, but should instead be defined only in accordance with the following claims and their equivalents.

I claim:

1. An electrical circuit apparatus 400, 900 comprising: at least one electrical component 402 encapsulated in electrical insulating material 404 wherein one or more leads 414 of the at least one electrical component 402 are exposed.

2. The apparatus of claim wherein the at least one electrical component 402 is selected from the group comprising area array integrated circuits, pin or post grid array (PGA), land grid array (LGA), quad flat pack (OFP), quad flat non leaded (QFN), discrete, and digital or analog components.

3. A method of positioning at least one electrical component 402 comprising: placing the at least one component 402 on a carrier 508, encapsulating the at least one electrical component in an electrically insulating material 404, and removing the carrier 508.

4. An electrical circuit apparatus 400, 900 comprising: at least one electrical component 402 encapsulated in an electrical insulating material 404 wherein one or more leads 414 of the at least one electrical component 402 are in electrical communication with respective one or more leads 410 on a printed circuit board 408.

5. The apparatus 400, 900 of claim 4 further comprising: one or more leads 414 of the at least one electrical component 402 in electrical communication with one or more respective intermediate connectors 412 within a joining material 406, and wherein the intermediate connectors 412 are in electrical communication with respective leads 410 on a printed circuit board 408.

6. The apparatus of claim 5 wherein the at least one electrical component 402 is selected from the group comprising area array integrated circuits, pin or post grid array (PGA), land grid array (LGA), quad flat pack (OFP), quad flat non leaded (QFN), discrete, and digital or analog components.

7. A method of connecting at least one electrical component 402 to a printed circuit board 408 comprising: placing the at least one electrical component 402 on a carrier 508, encapsulating the at least one component 402 in an electrically insulating material 404, removing the carrier 508, registering at least one component lead 414 with respective printed circuit board leads 410, and joining the at least one encapsulated component with the printed circuit board 408 wherein the at least one component lead 414 is in electrical communication with respective printed circuit board leads 410.

8. A method of connecting at least one electrical component 402 to a printed circuit board 408 comprising: placing the at least one electrical component 402 on a carrier 508, encapsulating the at least one component 402 in an electrically insulating material 404, removing the carrier 508, registering at least one component lead 414 with respective printed circuit board leads 410, placing an electrically conductive joining material 406 between the at least one encapsulated component and printed circuit board 408, and joining the at least one encapsulated component, the joining material 406, and the printed circuit board 408 wherein the at least one component lead 414 is in electrical communication with respective intermediate conductors 412 contained within the joining material 406 and the respective intermediate conductors 412 are in electrical communication with respective printed circuit board leads 410.

9. The method of claim 8 wherein the step of placing an electrically conductive joining material 406 is chosen from the group comprising disposing the joining material 406 on printed circuit board 408, disposing the joining material 406 on a subassembly 704, disposing the joining material 406 on printed circuit board 408 and disposing the joining material 406 on a subassembly 704, screen printing the joining material 406 on printed circuit board 408, screen printing the joining material 406 on a subassembly 704, screen printing the joining material 406 on printed circuit board 408 and screen printing the joining material 406 on a subassembly 704, stenciling the joining material 406 on printed circuit board 408, stenciling the joining material 406 on a subassembly 704, stenciling the joining material 406 on printed circuit board 408 and stenciling the joining material 406 on a subassembly 704, ink jetting the joining material 406 on printed circuit board 408, ink jetting the joining material 406 on a subassembly 704, ink jetting the joining material 406 on printed circuit board 408 and ink jetting the joining material 406 on a subassembly 704.
